(19) United States
(12) Patent Application Publication
(10) Pub. No.: US 2008/0191346 A1
(43) Pub. Date: Aug. 14, 2008

(54) Bump structure and manufacturing method thereof

(75) Inventors: Cheng-Hsuch Su, Kaohsiung (TW); Chuch-An Hsieh, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engeneering, Inc.

(21) Appl. No.: 11/889,955

(22) Filed: Aug. 17, 2007

(30) Foreign Application Priority Data
Feb. 9, 2007 (TW) 96104938

(51) Int. Cl. H01L 23/48; H01L 21/44

(52) U.S. Cl. 257/737; 438/614; 257/E23.021; 257/E21.575

(57) ABSTRACT

A bump structure comprises: a plurality of landing pads, a passive element, and a plurality of conductive bumps on a wafer. A method for manufacturing the bump comprises: providing a wafer with a plurality of landing pads, wherein the landing pads comprise a first landing pad and a second landing pad; forming a metal layer on each of the landing pads; forming a first photoresist to cover a surface of the wafer; forming a first opening on the first photoresist, wherein the first opening is disposed between the first landing pad and the second landing pad and exposes the partial metal layer on the first landing pad and the second landing pad; forming an electric resistance material in the first opening to electrically connect the first landing pad and the second landing pad; performing a curing step; and forming a plurality of conductive bumps on the metal layer of each of the landing pads.

### BACKGROUND OF THE INVENTION

1. Field of the Invention

The present invention generally relates to a bump structure and a manufacturing method thereof, more particularly, to a bump structure and a manufacturing method that use passive elements.

2. Description of the Prior Art

There are many types of electric elements in an electronic device as mobile phone, etc. Typical electric elements include active chips and passive elements. The active chip as IC, etc. can actively provide the operations of execution, activation, turn on/off, function, etc. On the other hand, the passive element as resistor, capacitor, or inductor has specific electric features but not providing active operations.

The most difference between the active chip and the passive element is the technology of manufacturing. The active chip is produced by the thin film process as explosion, development, coating, diffusion, etching, etc. Each film is seldom over one micron. The passive element is manufactured by the thick film process as halftone printing, hot sintering, etc. Each film is several times of a micron. Thus the resolution difference between a line for the active chip and a line for the passive element is huge.

As it can be seen, the passive element is hardly integrated with the active chip. At most, the silicon chip of an integrated circuit can be directly adhered to the main board by way of the technologies of flip chip, etc. so as to reduce the area of packaging.

For packaging chips, a plurality of bumps are added to connect to a packaging board. Each wafer is cut to become a plurality of dies. According to the number of a die, a plurality of metal pads are formed on the wafer, and a passivation layer is disposed between two metal pads. While manufacturing the bump, a UBM (under bump metallurgy) structure as Al/NiV/Cu, Ti/NiV/Cu, Ti/Cu/Ni, etc. is firstly formed on the metal pad. Continuously a tin material is formed on the UBM, and the tin material is cured to become a bump after a reflow step. As above descriptions, the prior art is nothing related to manufacture the passive element.

However, the passive element and the active chip are forced to be integrated together according to the tendency of an electronic device with slim weight, slim volume, and low-price. An important issue for integrating the passive element to the active chip will be a developing target to the people skilled in the art.

### SUMMARY OF THE INVENTION

The primary objective of the present invention is to provide a bump structure and a manufacturing method thereof, that is, the present invention is related to an integration of a passive element to the bump structure and a process to reduce noise.

The bump structure of the present invention comprises: a first landing pad and a second landing pad, the first landing pad and the second landing pad are disposed on the surface of a wafer, and a surface of each landing pad is covered by a metal layer; a passive element, having an electric resistant material, disposed between two landing pads is connected the metal layers on the first landing pad and the second landing pad respectively in order to electrically connect to the first landing pad and the second landing pad; and a plurality of conductive bumps, which are formed on the metal layers respectively.

The method for manufacturing the bumps comprises: providing a wafer with a plurality of landing pads, wherein the landing pads comprise a first landing pad and a second landing pad; forming a metal layer on each landing pads; forming a first photoresist to cover a surface of the wafer; forming a first opening on the first photoresist, wherein the first opening is disposed between the first landing pad and the second landing pad and exposes the partial metal layer on the first landing pad and the second landing pad; forming an electric resistance material in the first opening to electrically connect the first landing pad and the second landing pad; performing a curing step; and forming a plurality of conductive bumps on the metal layer of each landing pad.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a schematic view of a bump structure of the present invention;

FIG. 2A to FIG. 2K illustrate a schematic view of manufacturing the bump of a method of the present invention; and

FIG. 3 illustrates a schematic top view of the bump structure of FIG. 1.

### DETAILED DESCRIPTION OF THE INVENTION

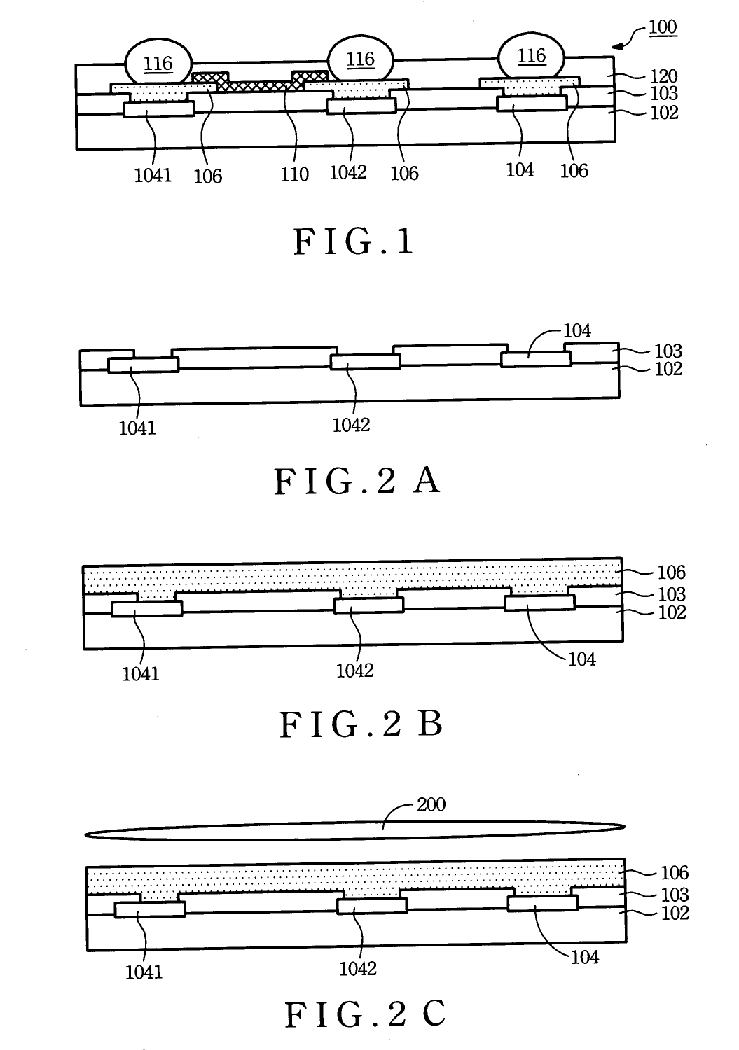

With reference to FIG. 1, a bump structure 100 of the present invention includes: a plurality of landing pads 104, including two landing pads 1041 and 1042, a passive element 110, and a plurality of conductive bumps 116 disposed on a wafer 102. Each landing pad has a metal layer 106 thereon.

The passive element 110 is made of an electric resistance material and disposed between the first landing pad 1041 and the second landing pad 1042, further that, the passive element 110 is connected to the metal layers 106 on the first landing pad 1041 and the second landing pad 1042 respectively. A plurality of conductive bumps 116 are formed on the metal layers 106 of the landing pads 104, 1041, and 1042 respectively. Therefore, the metal layers 106 are the UBMs below the conductive bumps 116.

The electric resistance material of the passive element 110 is a thermosetting material and consists of carbon and resin. The curing temperature thereof is 150° C. and 180° C.

The conductive bump is a ball, which is consisted of leand-tin alloy.

The metal layer is selected from one of the group of chromium, titanium, titanium-tungsten alloy, copper, nickel, chromium-copper alloy, nickel-vanadium alloy, nickel-aurum alloy, and the compositions.

Additionally, as shown in FIG. 1, the bump structure 100 further includes a passivation layer 103 and a protective layer 120. The passivation layer 103 is formed before forming the passive element 110, that is, a top surface of the wafer 102 has the passivation layer 103 connected to each of the landing pads 104, 1041, and 1042. In other words, the passivation layer 103 is disposed among the landing pads so as to separate the landing pads.

The protective layer 120 is to protect the circuit structure of the wafer 102 and formed on the passivation layer 103 and the passive element 110 in order to expose the conductive bump 116. The protective layer 120 is demanded by practical needs and made of PI, BCB, or other photosensitive materials, which are defined as photoresist materials.

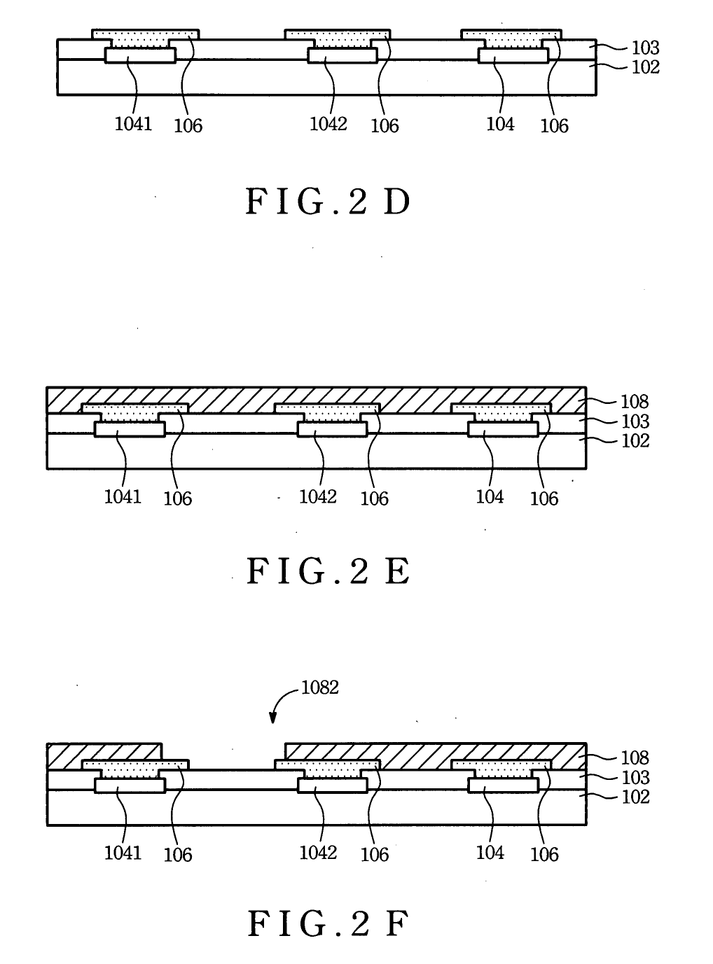

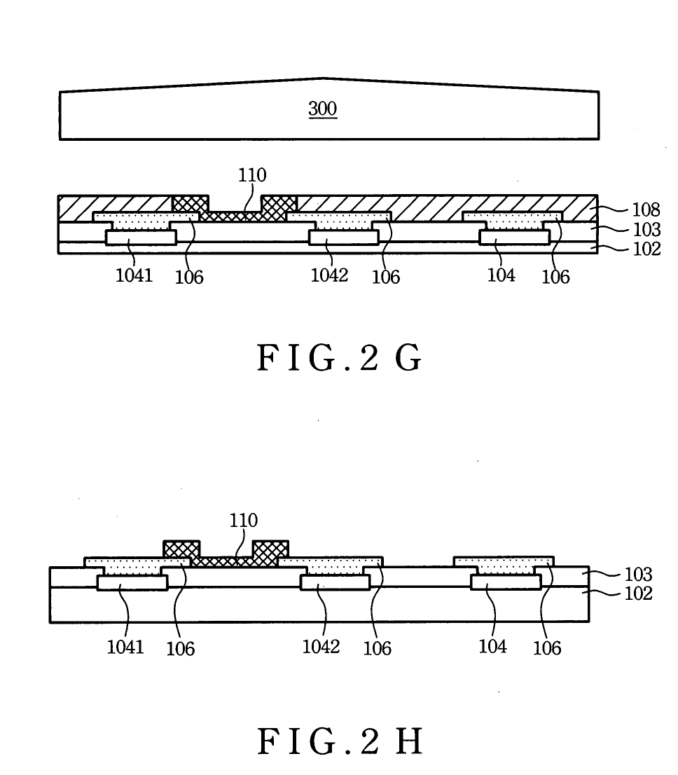

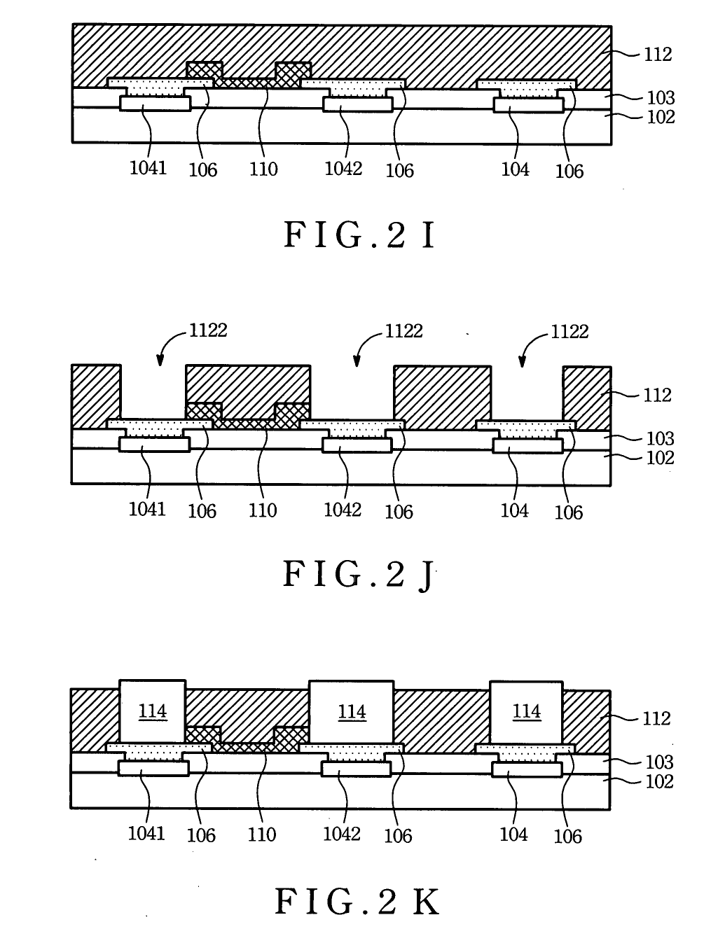

Please refer to FIG. 2A to FIG. 2K, the method of manufacturing the bumps includes the steps of: providing the wafer 102 and forming the plurality of landing pads 104, wherein each landing pads 104 includes the first landing pad 1041 and the second landing pad 1042 adjacent to the first landing pad 1041; forming the plurality of metal layers 106 on the landing pad 104, the first landing pad 1041, and the second landing pad 1042 respectively; alternatively forming the electric resistance material 110 between the first landing pad 1041 and the second landing pad 1042, and the electric resistance material 110 is connected to the metal layers 106 on the first landing pad 1041 and the second landing pad 1042 respectively, wherein the connections of the electrical resistance material 110, the first landing pad 1041, and the second landing pad 1042 are built up; and forming the plurality of conductive bumps 116 on the metal layers 106.

Detailed descriptions will be made as follows. With references to FIG. 2A to FIG. 2D, metals are sputtered on the wafer 102, and the plurality of landing pads, including the landing pad 104, the first landing pad 1041, and the second landing pad 1042, are formed by means of etching. Besides, the passivation layer 103 is on the surface of the wafer 102 and disposed among the landing pads. The other metal layer 106 is continuously sputtered on the landing pad 104 and the passivation layer 103 so as to form a UBM (under bump metallurgy) structure by using the apparatus 200 for performing a photolithography process. As shown in FIG. 1, the UBM is used to adhere the conductive bump 116 and the silicon dies formed from cutting the wafer 102, and the UBM can be a diffusion barrier between the silicon dies and the conductive bump 116. Additionally, two metal layers can be sputtered on the surface of the wafer 102 one after another, and the landing pad 104 and the UBMs are formed while in etching.

With references to FIG. 2E to FIG. 2G, the method for forming the electric resistance material on the wafer is described as follows. A first photoresist 108 can completely cover the surface of the wafer 102, wherein the first photoresist 108 is a dry-film. Then, a first opening 1082 is formed on the first photoresist 108 by way of exposure and development. The first opening 1082 is disposed between the first landing pad 1041 and the second landing pad 1042, and the partial metal layers 106 on the first landing pad 1041 and the second landing pad 1042 are exposed respectively. Continuously, the electric resistance material 110 is filled into the first opening 1082 by using the apparatus 300 for performing a printing process. The electric resistance material 110 is connected to the metal layers 106 on the first landing pad 1041 and the second landing pad 1042 respectively, then the electric resistance material 110 is electrically connected to the first landing pad 1041 and the second landing pad 1042.

In the preferred embodiment, the electric resistance material 110 can be applied a pre-drying process and a curing step, thus the electric resistance material 110 becomes a passive element 110, which is defined as a resistor. The pre-drying process is to heat the electric resistance material 110 to a temperature between 100° C. 25 to 150° C. The curing step is to heat the electric resistance material 110 to a temperature between 150° C. to 180° C.

Referring to FIG. 2H to FIG. 2K, the steps of forming the plurality of conductive bumps 116 on the metal layers 106 of the landing pads 104, 1041, and 1042 after forming the passive element 110 will be described:

First, the first photoresist 108 is removed, and a second photoresist 112 is formed to cover the surface of the wafer 102. By using the method of photolithography process, a plurality of second openings 1122 are formed on the second photoresist 112 to expose the metal layers 106 on the plurality of landing pads 104, 1041, and 1042. Next, a solder material 114 is printed on each second opening 1122. For example, the solder material 114 generally includes lead-tin alloy and is filled into each second opening 1122 by way of printing.

Then, a first reflow step is performed to the solder material 114, and the second photoresist is removed. Further, a second reflow is performed to the solder material 114. Therefore, the solder material 114 is to be the conductive bumps 116. The reflow temperature of the conductive bumps 116 is variable by different materials, such as a material with high lead content needing a higher reflow temperature.

At last, upon a practical demand, the protective layer 120 can be formed on the passivation layer 103 and the passive element 110 after forming the conductive bumps 116. The protective layer 120 is used to protect the circuit structure of the wafer 102 and expose the conductive bumps 116. Further that, the protective layer 120 is made of PI, BCB, or other photosensitive materials, which are defined as photoresist materials.

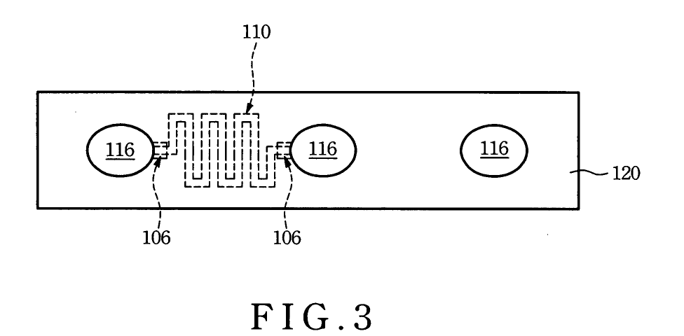

Referring to FIG. 3, which illustrates a schematic top view of the bump structure of FIG. 1. As shown in FIG. 3, the protective layer 120 covers the passive element 110 and the partial metal layers 106 and only exposes the conductive bumps 116. The passive element 110 is shaped as a curvature for the preferred embodiment.

It is to be noted that the electric resistant material is formed between two specific landing pads to construct a passive element. However, one passive element may not be enough to a wafer. Therefore, in practice, the electrical resistant material can be filled into any interval of two specific adjacent landing pads, which need a resistor. Therefore, a plurality of passive elements can be formed on one wafer.

Comparison to the prior art, the present invention has the merits of:
1. fully using the volume of an IC to accommodate more elements;
2. directly embedding the passive element into a die to save the space of a board or a PCB and decrease the number of active elements so as to reduce the noise while in conduction, wherein the more active elements go with a high rate of error.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for manufacturing bumps, comprising:
providing a wafer with a plurality of landing pads, wherein the landing pads comprise a first landing pad and a second landing pad;
forming a metal layer on each of the landing pads;
forming a first photoresist to cover a surface of the wafer;
forming a first opening on the first photoresist, wherein the first opening is disposed between the first landing pad and the second landing pad and exposes the partial metal layer on the first landing pad and the second landing pad;
forming an electric resistance material in the first opening to electrically connect the first landing pad and the second landing pad;
performing a curing step; and
forming a plurality of conductive bumps on the metal layer of each of the landing pads.

2. The method for manufacturing the bumps according to claim 1, wherein the step of forming the plurality of conductive bumps further comprises:
removing the first photoresist;
forming a second photoresist to cover the surface of the wafer;
forming a plurality of second openings on the second photoresist to expose the partial metal layer on the plurality of landing pads;
forming a solder material on each second opening; and
performing a first reflow step.

3. The method for manufacturing the bumps according to claim 2, wherein forming the solder material is performed by using a printing process.

4. The method for manufacturing the bumps according to claim 2, further comprising removing the second photoresist and performing a second reflow step after proceeding the first reflow step.

5. The method for manufacturing the bumps according to claim 1, further comprising performing a pre-drying step before performing the curing step, wherein the electric resistance material is heated to a temperature between 150° C. and 180° C. in the pre-drying step and the curing step.

6. The method for manufacturing the bumps according to claim 1, further comprising forming a protective layer on the surface of the wafer after forming the plurality of conductive bumps on the metal layer of each of the landing pads, wherein the protective layer exposes the conductive bumps.

7. A method for manufacturing bumps, comprising:
providing a wafer with a plurality of landing pads, wherein the landing pad comprises a first landing pad and a second landing pad adjacent to the first landing pad;
forming a metal layer on each of the landing pads;
forming an electric resistance material between the first landing pad and the second landing pad, wherein the electric resistance material electrically connects the first landing pad to the second landing pad through the metal layer; and
forming a plurality of conductive bumps on the metal layer of each of the landing pads.

8. The method for manufacturing the bumps according to claim 7, wherein forming the electric resistance material further comprises printing the electric resistance material in between the first landing pad and the second landing pad.

9. The method for manufacturing the bumps according to claim 7, wherein forming the electric resistance material further comprises:
forming a first photoresist to cover the surface of the wafer;
forming a first opening on the first photoresist, wherein the first opening is disposed between the first landing pad and the second landing pad and exposes the partial metal layer on the first landing pad and the second landing pad; and
printing the electric resistance material in the first opening.

10. The method for manufacturing the bumps according to claim 7 further comprising performing a pre-drying step before performing the curing step, wherein the electric resistance material is heated to a temperature between 150° C. and 180° C. in the pre-drying step and the curing step.

11. The method for manufacturing the bumps according to claim 9, wherein forming the plurality of conductive bumps further comprises:
removing the first photoresist;
forming a second photoresist to cover the surface of the wafer;
forming a plurality of second openings on the second photoresist to expose the metal layer on the plurality of landing pads;
printing a solder material on each second opening;
performing a first reflow step;
removing the second photoresist; and
performing a second reflow to the solder material.

12. The method for manufacturing the bumps according to claim 7, further comprising forming a protective layer on the surface of the wafer after forming the plurality of conductive bumps on the metal layer of each of the landing pads, wherein the protective layer exposes the conductive bumps.

13. A bump structure, comprising:
a wafer;
a first landing pad and a second landing pad being disposed on a surface of the wafer, each of the first landing pad and the second landing pad having a metal layer;
a passive element having an electric resistance material, which is disposed between the first landing pad and the second landing pad and connected the metal layers on the first landing pad and the second landing pad respectively so as to electrically connect to the first landing pad and the second landing pad; and
a plurality of conductive bumps being formed on the metal layers.

14. The bump structure according to claim 13, wherein the electric resistance material of the passive element is a thermosetting material.

15. The bump structure according to claim 13, wherein the electric resistance material of the passive element consists of carbon and resin.

16. The bump structure according to claim 13, wherein the electric resistance material of the passive element has a curing temperature between 150° C. and 180° C.

17. The bump structure according to claim 13, wherein the conductive bump is a ball.

18. The bump structure according to claim 13, wherein the conductive bump consists of lead-tin alloy.

19. The bump structure according to claim 13, wherein the metal layer is selected from one of the group of chromium, titanium, titanium-tungsten alloy, copper, nickel, chromium-copper alloy, nickel-vanadium alloy, nickel-aurum alloy, and the compositions.

20. The bump structure according to claim 13, wherein a top surface of the wafer has a passivation layer, the bump structure has a protective layer formed on the passivation layer and the passive element, and the conductive bumps are exposed.
